(19) United States
(12) Patent Application Publication
(10) Pub. No.: US 2025/0133873 A1
(43) Pub. Date: Apr. 24, 2025

(54) LIGHT-EMITTING DEVICE AND LIGHT-EMITTING APPARATUS

(71) Applicant: XIAMEN SAN’AN OPTOELECTRONICS CO., LTD., Xiamen (CN)

(72) Inventors: Qiuyan FANG, Xiamen (CN); Kechuang LIN, Xiamen (CN); Chenke HSU, Nanan City (CN); Tung-Kai LIU, Xiamen (CN)

(21) Appl. No.: 18/921,628

(22) Filed: Oct. 21, 2024

(30) Foreign Application Priority Data
Oct. 23, 2023 (CN) 202311380157.7

(51) Int. Cl. H01L 33/24; H01L 33/38; H01L 33/44

(52) U.S. Cl. CPC H10H 20/821; H10H 20/8312; H10H 20/84

(57) ABSTRACT

A light-emitting device includes a first semiconductor layer having a first surface and a second surface that are opposite to each other, an active layer disposed on the first surface of the first semiconductor layer, a second semiconductor layer disposed on the active layer away from the first semiconductor layer, a mesa defined by a portion of the first semiconductor layer that is not covered by the active layer, and a recess extending through the second semiconductor layer into the first semiconductor layer. The recess, when being viewed from above the light-emitting device, is closer to a center of the first semiconductor layer than the mesa. A light-emitting apparatus including a circuit board and the light-emitting device is also provided.

### CROSS-REFERENCE TO RELATED APPLICATION

This application claims priority to Chinese Invention Patent Application No. CN202311380157.7, filed on Oct. 23, 2023, the entire disclosure of which is incorporated by reference herein.

### FIELD

The disclosure relates to semiconductor manufacturing, and more particularly to a light-emitting device and a light-emitting apparatus.

### BACKGROUND

Light-emitting diodes (LEDs) are semiconductor light-emitting devices usually made of GaN, GaAs, GaP, GaAsP, etc., and have light-emitting PN junctions. LEDs have advantages such as high luminous intensity, high efficiency, small size, long lifespan, etc., and are considered to be one of the light sources having the most potential. LEDs have been widely applied in lighting, monitoring, high-definition broadcasting, high-end theater, office display, conference communications, virtual reality, etc. In recent years, LEDs often have problems such as low brightness and low light-emitting efficiency. Therefore, there is room for improvement in this field.

It should be noted that the information disclosed in the background of this disclosure is merely intended to enhance the understanding of the general technology of the present disclosure, and should not be considered as recognizing or implying in any way that the information constitutes prior art already well known to a person of ordinary skill in the art.

### SUMMARY

Therefore, an object of the disclosure is to provide a light-emitting device and a light-emitting apparatus that can alleviate at least one of the drawbacks of the prior art.

According to an aspect of the disclosure, the light-emitting device includes a first semiconductor layer, an active layer, a second semiconductor layer, a mesa, and a recess. The first semiconductor layer has a first surface and a second surface that are opposite to each other. The active layer is disposed on the first surface of the first semiconductor layer. The second semiconductor layer is disposed on the active layer away from the first semiconductor layer. The mesa is defined by a portion of the first semiconductor layer that is not covered by the active layer. The recess extends through the second semiconductor layer into the first semiconductor layer. The recess, when being viewed from above the light-emitting device, is closer to a center of the first semiconductor layer than the mesa.

According to another aspect of the disclosure, a light-emitting apparatus includes a circuit board and the light-emitting device as described previously and disposed on the circuit board.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view of a light-emitting device according to an embodiment of the disclosure.

FIG. 2 is a schematic sectional view taken along line F-F of FIG. 1.

FIG. 3 is a schematic view of a central region and a peripheral region of a first semiconductor layer according to the embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

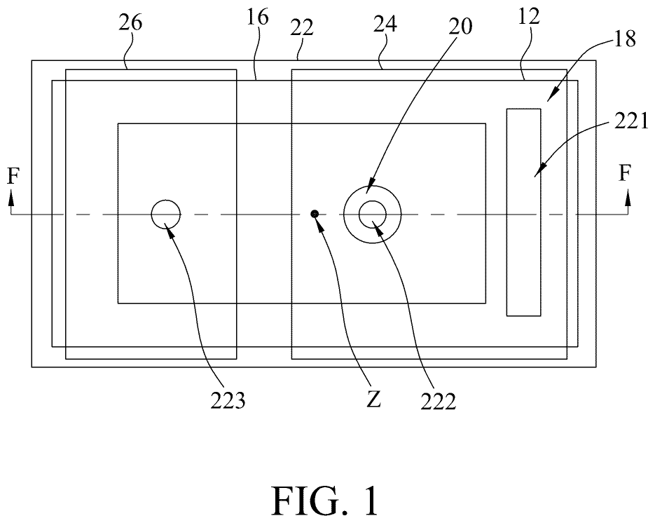

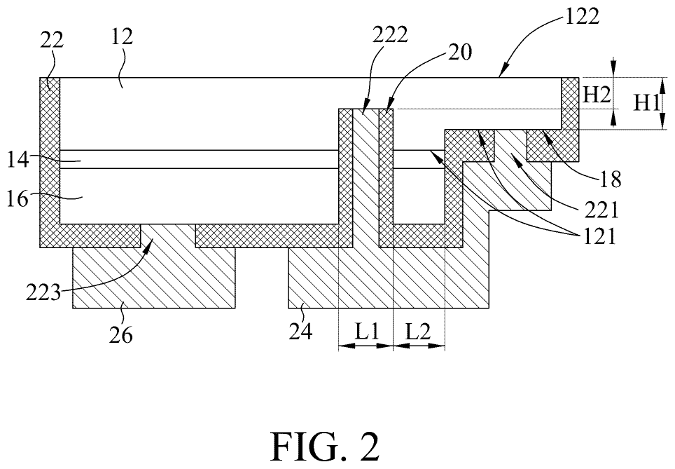

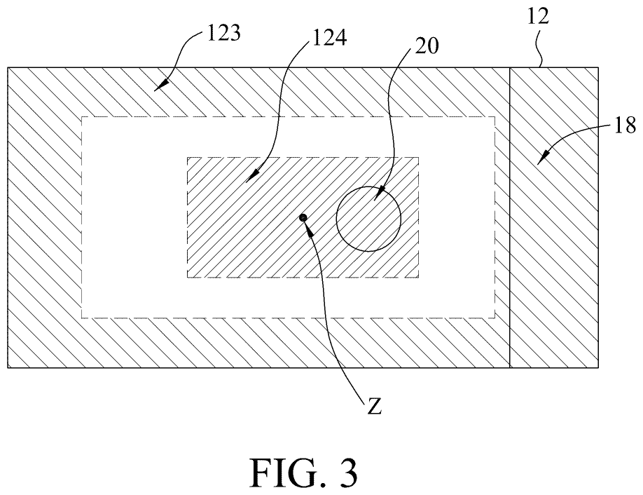

Referring to FIGS. 1 to 3, FIG. 1 is a schematic top view of a light-emitting device according to an embodiment of the disclosure. FIG. 2 is a schematic sectional view taken along line F-F of FIG. 1, and FIG. 3 is a schematic view of a central region 124 and a peripheral region 123 of a first semiconductor layer 12 according to the embodiment of the disclosure. To achieve at least one of the described advantages or other advantages, the embodiment of the light-emitting device is provided. As shown in the figures, the light-emitting device includes the first semiconductor layer 12, an active layer 14, and a second semiconductor layer 16.

The first semiconductor layer 12 has a first surface 121 and a second surface 122 that are opposite to each other. In this embodiment, the first surface 121 and the second surface 122 are a lower surface and an upper surface of the first semiconductor layer 12, respectively. The first semiconductor layer 12 may be an n-type semiconductor layer that provides electrons to the active layer 14 when being applied with power. In some embodiments, the first semiconductor layer 12 includes an n-type doped nitride layer. The n-type doped nitride layer may include n-type impurities. The n-type impurities may include Si, Ge, Sn, or combinations thereof.

The active layer 14 is disposed on the first surface 121 of the first semiconductor layer 12. The active layer 14 may have a single quantum well structure. In some embodiments, the active layer 14 has a multiple quantum well structure that includes well layers and barrier layers that are alternately stacked, such as GaN/AIGaN, InAIGaN/InAIGaN, or InGaN/AIGaN multiple quantum well structures. In addition, compositions of the well layers of the active layer 14 and thicknesses of the well layers determine a wavelength of light generated. To improve light-emitting efficiency of the active layer 14, depth of the quantum well structure, number of pairs of the well layers and the barrier layers, thicknesses of the well layers and the barrier layers, and/or other characteristics in the active layer 14 may be adjusted.

The second semiconductor layer 16 is disposed on the active layer 14 away from the first semiconductor layer 12. That is to say, the active layer 14 is disposed between the first semiconductor layer 12 and the second semiconductor layer 16. The second semiconductor layer 16 may be a p-type semiconductor layer that provides holes to the active layer 14 when being applied with power. In some embodiments, the second semiconductor layer 16 includes a p-type doped nitride layer. The p-type doped nitride layer may include p-type impurities. The p-type impurities may include Mg, Zn, Be, or combinations thereof. The second semiconductor layer 16 may have a single-layered structure or a multilayer structure having different compositions.

The light-emitting device includes a mesa 18 and a recess 20. The mesa 18 is defined by a portion of the first semiconductor layer 12 that is not covered by the active layer 14. That is to say, portions of the second semiconductor layer 16 and the active layer 14 corresponding to the mesa 18 are removed to expose the first semiconductor layer 12, thereby forming the mesa 18. As shown in the figures, the mesa 18 may subsequently be used for disposition of a first electrode 24. Configuration of the mesa 18 is not limited to that shown in the figures, and may be designed according to an actual size and a shape of a chip. In some embodiments, the mesa 18 surrounds the active layer 14. In some embodiments, the mesa 18 and the recess 20 are formed by a single processing step.

The recess 20 extends through the second semiconductor layer 16 into the first semiconductor layer 12. It should be noted that, the recess 20 does not penetrate the first semiconductor layer 12 completely; instead, the recess 20 extends into the first semiconductor layer 12 to a certain depth. The recess 20, when being viewed from above the light-emitting device, is closer to a center (Z) of the first semiconductor layer 12 than the mesa 18. The center (Z) refers to a center position of the light-emitting device. When the first semiconductor layer 12 has a regular geometric shape, the center (Z) may be a center position of the regular geometric shape. When the first semiconductor layer 12 has an irregular geometric shape, the center (Z) may be more difficult to determine. The center (Z) may refer to a central region roughly corresponding to a center of the irregular geometric shape. By virtue of such design that simultaneously utilizes the mesa 18 and the recess 20 as a current spreading path, light diffusion of the light-emitting device may be effectively improved and brightness and heat sinking of the light-emitting device may be increased. At the same time, the recess 20 is closer to the center (Z) of the first semiconductor layer 12, current spreading is radial, which is conducive to current spreading and may ensure that the first electrode 24 and a second electrode 26, which are to be subsequently disposed, are equal in size, thereby increasing a contact area between the first electrode 24 and a substrate and a contact area between the second electrode 26 and the substrate, and enhancing device reliability. When the light-emitting device is designed with only the mesa 18 but not the recess 20, current flows from a p-type semiconductor layer linearly to an n-type electrode, which is not conducive for current spreading.

A first perpendicular distance (H1) between the mesa 18 and the second surface 122 of the first semiconductor layer 12 is greater than a second perpendicular distance (H2) between the recess 20 and the second surface 122 of the first semiconductor layer 12. That is to say, a depth of the recess 20 is greater than a depth of the mesa 18, so as to allow the current flowing to the mesa 18 and the recess 20 evenly. With a current path being shorter, current spreading may be improved. In some embodiments, the first perpendicular distance (H1) ranges from 0.5 μm to 2.5 μm, and the second perpendicular distance (H2) ranges from 0.5 μm to 2.5 μm. In some embodiments, the first perpendicular distance (H1) may be equal to the second perpendicular distance (H2), or the first perpendicular distance (H1) may be smaller than the second perpendicular distance (H2).

In some embodiments, referring to FIG. 3, the first semiconductor layer 12 includes the peripheral region 123 and the central region 124. The mesa 18 is located in the peripheral region 123, and the recess 20 is located in the central region 124. Areas where the peripheral region 123 and the central region 124 are located are shown by different shadings in the figures.

In this embodiment, when the first semiconductor layer 12 is viewed from above the light-emitting device, the central region 124 represents a region that expands outwardly from the center (Z) of the first semiconductor layer 12 to peripheral sides of the first semiconductor layer 12. An area of a projection of the central region 124 on an imaginary plane that is parallel to the first semiconductor layer 12 occupies 10% to 45% of an area of a projection of the first semiconductor layer 12 on the imaginary plane. A distance from the center (Z) to each of the peripheral sides of the first semiconductor layer 12 may be different. In some embodiments, when the first semiconductor layer 12 is viewed from above the light-emitting device, the central region 124 represents a region that expands outwardly from the center (Z) of the first semiconductor layer 12 to peripheral sides of the first semiconductor layer 12, and a maximum dimension of the central region 124 ranges from 5 μm to 85 μm. The distance from the center (Z) to each of the peripheral sides of the first semiconductor layer 12 may be different. The central region 124 may have an irregular shape.

When the first semiconductor layer 12 is viewed from above the light-emitting device, the peripheral region 123 represents a region that expands inwardly from the peripheral sides of the first semiconductor layer 12 to the center (Z) of the first semiconductor layer 12, and an area of a projection of the peripheral region 123 on the imaginary plane occupies 55% to 90% of the area of the projection of the first semiconductor layer 12 on the imaginary plane. A distance from each of the peripheral sides of the first semiconductor layer 12 to the center (Z) may be different. The peripheral region 123 may have an irregular shape. In some embodiments, a gap exists between the peripheral region 123 and the central region 124. That is to say, the peripheral region 123 is not connected to the central region 124. In some embodiments, the peripheral region 123 and the central region 124 may be overlapped.

In some embodiments, a cross-sectional area of the recess 20 on the imaginary plane that is parallel to the first semiconductor layer 12 occupies 2% to 20% of an area of the first semiconductor layer 12, and an area of the mesa 18 occupies 5% to 35% of the area of the first semiconductor layer 12, thereby further improving an ability of current spreading.

To even further improve the ability of current spreading, a dimension (L1) of the recess 18 ranges from 0.5 μm to 15 μm, and a minimum distance (L2) between the recess 18 and the mesa 20 ranges from 0.5 μm to 15 μm. If the dimension (L1) of the recess 18 is too great, the light-emitting efficiency of the active layer 14 may be affected. If the minimum distance (L2) between the recess 18 and the mesa 20 is too small, possibility of the recess 18 and the mesa 20 interfering one another is increased. If the minimum distance (L2) between the recess 18 and the mesa 20 is too great, optoelectronic performance of the light-emitting device may be affected.

The light-emitting device further includes an insulation layer 22, a first electrode 24, and a second electrode 26.

The insulation layer 22 covers the first semiconductor layer 12, the active layer 14 and the second semiconductor layer 16, and has a first opening 221, a second opening 222 and a third opening 223. The first opening 221 exposes the mesa 18. The second opening 222 is disposed within the recess 20 and exposes a portion of the first semiconductor layer 12. The third opening 223 exposes the second semiconductor layer 16.

The insulation layer 22 includes a non-conductive material. The non-conductive material may be an inorganic material or a dielectric material. The inorganic material may include silicone. The dielectric material may include an electrically insulating material such as aluminum oxide, silicon nitride, silicon oxide, titanium oxide, or magnesium fluoride. For example, the insulation layer 22 may be made of silicon dioxide, silicon nitride, titanium oxide, tantalum oxide, niobium oxide, barium titanate, or combinations thereof. For example, the insulation layer 22 may be a Bragg reflective layer structure that is formed by alternatively stacking two different materials each having a different reflective index.

The first electrode 24 is disposed on the insulation layer 22 and is electrically connected to the first semiconductor layer 12 through the first opening 221 and the second opening 222. The first electrode 24 covers the first opening 221 and the second opening 222 to ensure a sufficient contact area for improving subsequent electrical connection with the substrate.

The second electrode 26 is disposed on the insulation layer 22 and is electrically connected to the second semiconductor layer 16 through the third opening 223. In some embodiments, a surface of the first electrode 24 facing away from the insulation layer 22 and a surface of the second electrode 26 facing away from the insulation layer 22 are flush with each other, thereby increasing stability of the light-emitting device. Each of the first electrode 24 and the second electrode 26 may be a metal pad that is made of a metallic material, and may be a single-layered, a double-layered, or multilayer structure such as Ti/Al, Ti/Al/Ti/Au, Ti/Al/Ni/Au, V/AI/Pt/Au, etc.

In some embodiments, the light-emitting device is a micro light-emitting device and has a size that is no greater than 100 μm.

In some embodiments, each of the recess 20 and the mesa 18 may be formed by a MESA photomask that may effectively control etching angles for better growth of the insulation layer 22 in a subsequent step to protect sidewalls, thereby avoiding sidewall defects, effectively improving forming of windows, and miniaturizing chip trenches.

A light-emitting apparatus is also provided and includes a circuit board and the light-emitting device as described in any of the previous embodiments and disposed on the circuit board.

In summary, by virtue of the recess 20 and the mesa 18, the light-emitting device and the light-emitting apparatus according to the disclosure may effectively improve light diffusion, brightness, and heat sinking of the light-emitting device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a first semiconductor layer having a first surface and a second surface that are opposite to each other;
an active layer disposed on said first surface of said first semiconductor layer; and
a second semiconductor layer disposed on said active layer away from said first semiconductor layer,
wherein said light-emitting device includes a mesa and a recess, said mesa being defined by a portion of said first semiconductor layer that is not covered by said active layer, said recess extending through said second semiconductor layer into said first semiconductor layer, said recess, when being viewed from above said light-emitting device, being closer to a center of said first semiconductor layer than said mesa.

2. The light-emitting device as claimed in claim 1, wherein a first perpendicular distance between said mesa and said second surface of said first semiconductor layer is greater than a second perpendicular distance between said recess and said second surface of said first semiconductor layer.

3. The light-emitting device as claimed in claim 2, wherein said first perpendicular distance ranges from 0.5 μm to 2.5 μm.

4. The light-emitting device as claimed in claim 2, wherein said second perpendicular distance ranges from 0.5 μm to 2.5 μm.

5. The light-emitting device as claimed in claim 1, wherein said first semiconductor layer includes a peripheral region and a central region, said mesa being located in said peripheral region, said recess being located in said central region.

6. The light-emitting device as claimed in claim 5, wherein:
when said first semiconductor layer is viewed from above said light-emitting device, said central region represents a region that expands outwardly from said center of said first semiconductor layer to peripheral sides of said first semiconductor layer, and an area of a projection of said central region on an imaginary plane that is parallel to said first semiconductor layer occupies 10% to 45% of an area of a projection of said first semiconductor layer on said imaginary plane; and
when said first semiconductor layer is viewed from above said light-emitting device, said peripheral region represents a region that expands inwardly from said peripheral sides of said first semiconductor layer to said center of said first semiconductor layer, and an area of a projection of said peripheral region on said imaginary plane occupies 55% to 90% of said area of said projection of said first semiconductor layer on said imaginary plane.

7. The light-emitting device as claimed in claim 5, wherein:
when said first semiconductor layer is viewed from above said light-emitting device, said central region represents a region that expands outwardly from said center of said first semiconductor layer to peripheral sides of said first semiconductor layer, and a maximum dimension of said central region ranges from 5 μm to 85 μm; and
when said first semiconductor layer is viewed from above said light-emitting device, said peripheral region represents a region that expands inwardly from said peripheral sides of said first semiconductor layer to said center of said first semiconductor layer, and an area of a projection of said peripheral region on said imaginary plane occupies 55% to 90% of said area of said projection of said first semiconductor layer on said imaginary plane.

8. The light-emitting device as claimed in claim 1, wherein a cross-sectional area of said recess on an imaginary plane that is parallel to said first semiconductor layer occupies 2% to 20% of an area of said first semiconductor layer, and an area of said mesa occupies 5% to 35% of said area of said first semiconductor layer.

9. The light-emitting device as claimed in claim 1, wherein a dimension of said recess ranges from 0.5 μm to 15 μm.

10. The light-emitting device as claimed in claim 1, wherein a minimum distance between said recess and said mesa ranges from 0.5 μm to 15 μm.

11. The light-emitting device as claimed in claim 1, further comprising an insulation layer, a first electrode, and a second electrode, said insulation layer covering said first semiconductor layer, said active layer and said second semiconductor layer, and having a first opening, a second opening and a third opening, said first opening exposing said mesa, said second opening being disposed within said recess and exposing a portion of said first semiconductor layer, said third opening exposing said second semiconductor layer, said first electrode being disposed on said insulation layer and being electrically connected to said first semiconductor layer through said first opening and said second opening, said second electrode being disposed on said insulation layer and being electrically connected to said second semiconductor layer through said third opening.

12. The light-emitting device as claimed in claim 11, wherein a surface of said first electrode facing away from said insulation layer and a surface of said second electrode facing away from said insulation layer are flush with each other.

13. The light-emitting device as claimed in claim 11, wherein said first electrode covers said first opening and said second opening.

14. The light-emitting device as claimed in claim 1, wherein a size of said light-emitting device is no greater than 100 μm.

15. A light-emitting apparatus, comprising:
a circuit board; and
said light-emitting device as claimed in claim 1 and disposed on said circuit board.
